(19) United States
(12) Patent Application Publication
(10) Pub. No.: US 2024/0339382 A1
(43) Pub. Date: Oct. 10, 2024

(54) MOLDED PACKAGE WITH AN INTERCHANGEABLE LEADFRAME

(71) Applicant: TEXAS INSTRUMENTS INCORPORATED, DALLAS, TX (US)

(72) Inventors: YOU CHYE HOW, MELAKA (MY); HUAY YANN TAY, MELAKA (MY); WEI LI JULIEN MOK, MELAKA (MY)

(21) Appl. No.: 18/297,088

(22) Filed: Apr. 7, 2023

(51) Int. Cl. H01L 23/495; H01L 21/48; H01L 21/56; H01L 23/00

(52) U.S. Cl. CPC H01L 23/49541; H01L 21/4842; H01L 21/563; H01L 21/565; H01L 23/49582; H01L 24/09; H01L 24/16; H01L 2224/09132; H01L 2224/09133; H01L 2224/16245; H01L 2924/1815; H01L 2924/182

(57) ABSTRACT

An electronic device that includes a leadframe having contact pads, where at least two adjacent contact pads of the contact pads are disconnected from each other via a slot. A die includes input/output pins, where the input/output pins are connected to respective contact pads of the contact pads on the leadframe. Interconnects connect the input/output pins to the respective contact pads. A mold compound encapsulates the die and the interconnects.

### TECHNICAL FIELD

The present disclosure relates to an electronic device and more specifically, to an integrated circuit package that includes an interchangeable leadframe and method of making the same.

Leadframe type integrated circuit (IC) packages include contact pads that are connected to input/output (I/O) pins on a die. The number of contact pads on the leadframe and the number of I/O pins on the die are typically the same. For example, in an applications where a die has 9, 16, or 25 I/O pins, the leadframe will also have 9, 16, or 25 contact pads respectively. Thus, the leadframe is configured to match the die and thus each die requires a specific leadframe. As a result, the leadframes are not interchangeable in different applications where the number of I/O pins of the dies in the different applications differ.

### SUMMARY

In described examples, an electronic device includes a leadframe having a plurality of contact pads, where at least two adjacent contact pads of the plurality of contact pads are disconnected from each other via a slot. A die includes a plurality of input/output pins, where the plurality of input/output pins are connected to respective contact pads of the plurality of contact pads on the leadframe. A plurality of interconnects connect the plurality of input/output pins to the respective contact pads. A mold compound encapsulates the die and the plurality of interconnects.

In still another described example, a method of fabricating an electronic device includes providing a leadframe, where the leadframe has a plurality of contact pads and a plurality of leads connected to the plurality contact pads. A slot is formed between at least two adjacent contact pads of the plurality of contact pads to disconnect the at least two adjacent contact pads from each other. A die is attached to the leadframe and a mold compound is formed over a portion of the leadframe having the plurality of contact pads and over the die.

### BRIEF DESCRIPTION OF THE DRAWINGS

FIGS. 1A-1C are cross-sectional views of example electronic devices.

FIG. 2 is a top view of a leadframe of the example electronic devices.

FIGS. 3A-3F are bottom view of example dies.

FIG. 4 is a block diagram flow chart explaining a fabrication process of the electronic device in FIG. 1A.

FIGS. 5A and 5B illustrate top and cross sectional views respectively of the leadframe in the early stages of fabrication of the electronic device of FIG. 1A.

FIGS. 5C and 5D illustrate top and cross sectional views respectively of the leadframe after removal of connecting bars of the electronic device of FIGS. 5A and 5B.

FIGS. 5E and 5F illustrate top and cross sectional views respectively of the electronic device of FIGS. 5C and 5D after attachment of a die.

FIGS. 5G and 5H illustrate top and cross sectional views respectively of the electronic device of FIGS. 5E and 5F after attachment the formation of a mold compound.

FIGS. 5I and 5J illustrate top and cross sectional views respectively of the electronic device of FIGS. 5G and 5H after removal of tie bars.

FIGS. 5K and 5L illustrate top and cross sectional views respectively of the electronic device of FIGS. 5I and 5J after formation of external leads.

FIG. 5M is a bottom view of the electronic device of FIG. 5K.

### DETAILED DESCRIPTION

Leadframe type integrated circuit (IC) packages include contact pads that are connected to input/output (I/O) pins on a die (e.g., flip-chip die). The number of contact pads on the leadframe and the number of I/O pins on the die are typically the same. For example, in an applications where a die has 9, 16, or 25 I/O pins, the leadframe will also have 9, 16, or 25 contact pads respectively. Thus, the leadframe is configured to match the die and thus each die requires a specific and different leadframe. As a result, the leadframes are not interchangeable in different applications where the number of I/O pins of the dies in the different applications differ. The lack of interchangeability results in higher inventory and fabrication costs.

Disclosed herein is an electronic device and method of fabricating the electronic device that overcomes the challenges described above. The electronic device includes an interchangeable leadframe that can be used in different applications where the number of input/output (I/O) pins on a die differ from application to application. The leadframe includes contact pads that are connected to external leads and where adjacent contact pads are initially connected to each other. During fabrication of the electronic device and depending on the application of the electronic device, at least two adjacent contact pads are disconnected from each other via a laser process. Any number of adjacent contact pads on the leadframe can be disconnected from each other depending on the application of the electronic device to achieve the proper I/O pin requirement of the die.

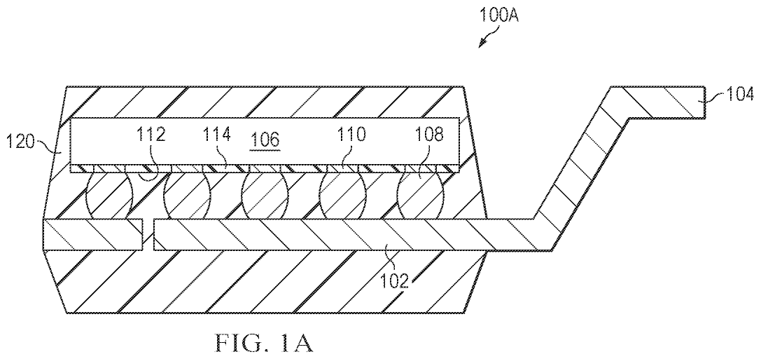

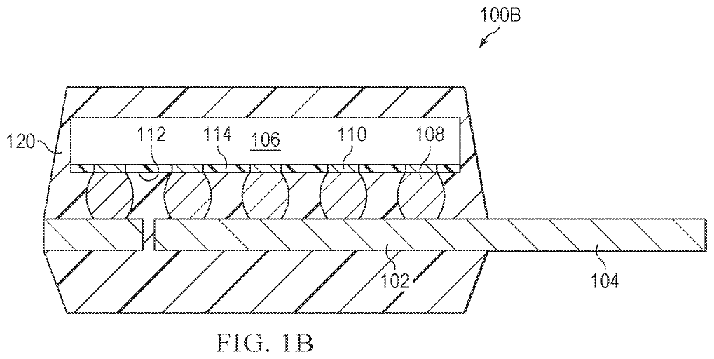

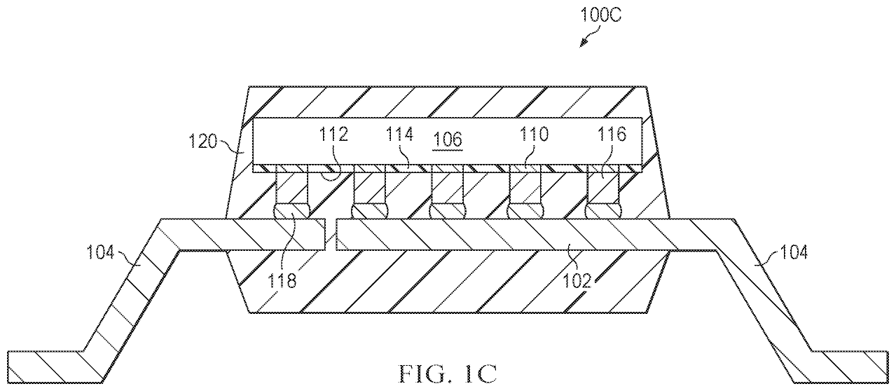

FIGS. 1A-1C are cross-sectional views of example electronic devices (e.g., integrated circuit (IC) packages) 100A-100C comprising a leadframe 102 that includes contact pads (not shown in FIGS. 1A-1C) and external leads 104. The electronic devices further include a die 106 connected to the leadframe 102 via interconnects (e.g., solder) 108. The electronic devices 100A, 100B, 100C can comprise an integrated circuit (IC) package including, but not limited to a single in-line package (SIP), a double in-line package (DIP), a surface mount package (SMP), a ball-grid array (BGA) package, a quad flat no-lead (QFN) package, a quad-flat package (QFP), etc. For example, the electronic device 100A illustrated in FIG. 1A is a SIP having a formed or bent external lead 104, the example electronic device 100B illustrated in FIG. 1B is SIP having a straight external lead 104, and the example electronic device 100C illustrated in FIG. 1C is a DIP having external leads 104 extending away from each other on opposite sides of the electronic device 100C. Thus, the example electronic devices 100A, 100B, 100C illustrated in FIGS. 1A-1C are for illustrative purposes only and is not intended to limit the scope of the invention.

The die 106 includes input/output (I/O) pins 110 disposed on an active surface 112 of the die 106. The die 106 can include an optional passivation layer 114 disposed on the active surface 112 of the die 106. The passivation layer, however, surrounds each I/O pin 110. As will be illustrated further below, the I/O pins 110 align with and are connected to respective contact pads on the leadframe 102 via the interconnects 108.

In an alternative example illustrated in FIG. 1C, metal pillars 116 may be attached to the die 106. Specifically, the metal pillars 116 are aligned with and are connected to the I/O pins 110 on the die 106. An interconnect (e.g., solder film, solder paste, solder balls) 118 is disposed on a surface of the metal pillars 116 opposite the surface connected to the die 106. Thus, in the example illustrated in FIG. 1C, the metal pillars 116 connect to the respective contact pads on the leadframe 102 via the interconnect 118. A reflow process is performed to adhere the die 106 to the leadframe 102 via the interconnect 118.

The electronic devices 100A, 100B, 100C further include a mold compound 120. The mold compound 120 covers the leadframe 102 with the exception of the external leads 104. In addition, the mold compound 120 encapsulates the die 106, the interconnects 108, and the optional metal pillars 116.

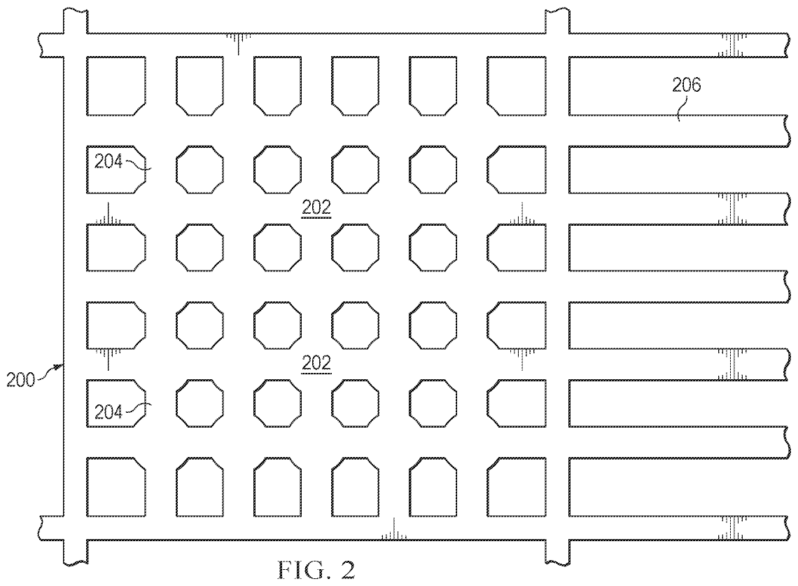

FIG. 2 is an example interchangeable leadframe 200 that includes 25 contact pads 202 in a 5×5 array where adjacent contact pads 202 are connected to each other via connecting bars 204. Thus, all the contact pads 202 are interconnected to each other. The leadframe 200 further includes leads 206 that connect to a row or a column of contact pads 202 that are closest to at least one side of the leadframe 200. Thus, since the contact pads 202 are interconnected via the connecting bars 204, the leads 206 are then interconnected with all the contact pads 202. It is to be understood that the leadframe 200 can include any number of contact pads 202 and can include a second set of leads that are connected to a second row or column of contact pads 202 on an opposite side of the leadframe 200. Thus, the example leadframe 200 illustrated in FIG. 2 is for illustrative purposes only and is not intended to limit the scope of the invention.

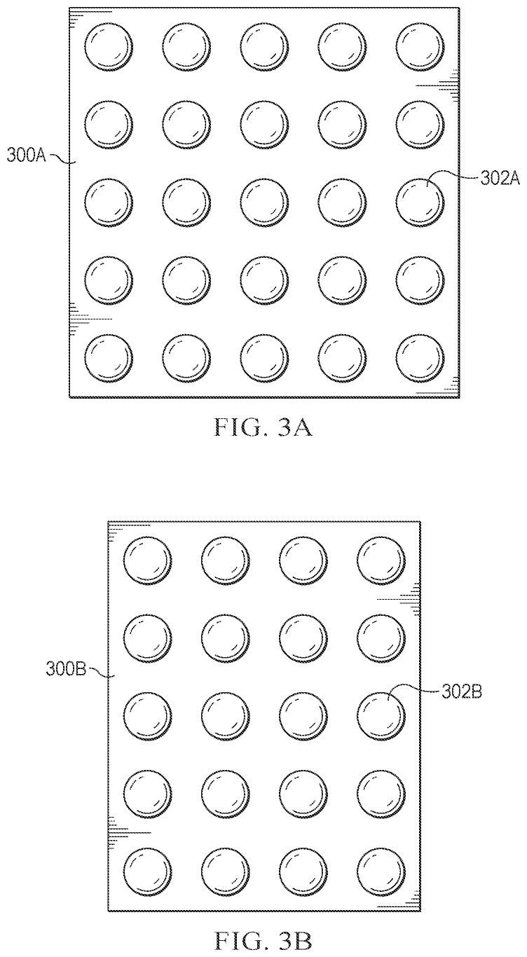

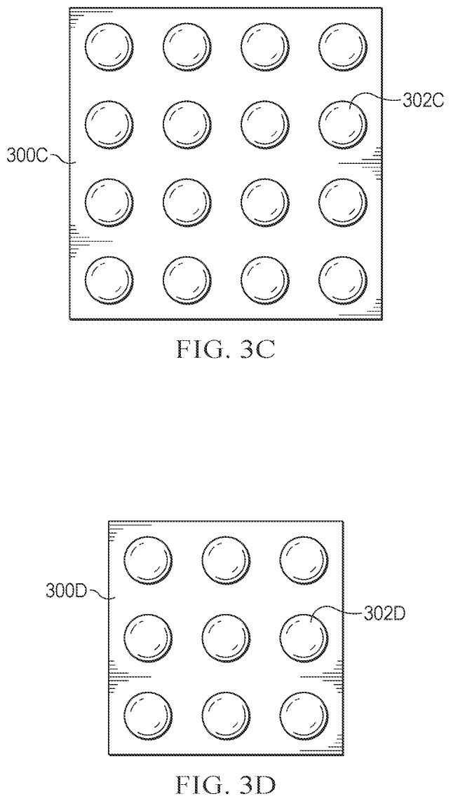

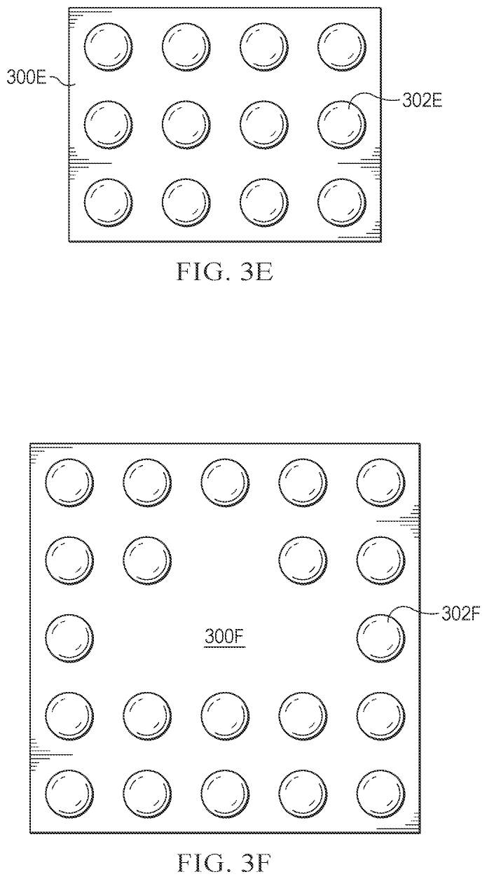

FIGS. 3A-3F are some example configurations of dies 300A-300F (e.g., flip-chip dies) that can be used in an IC package with the leadframe 200 illustrated in FIG. 2. As illustrated in FIGS. 3A-3F, the different configured dies 300A-300F can have any number of I/O pins 302A-302F (collectively 302) and can have a square or rectangular shape. For example, die 300A has 25 I/O pins 302A, die 300B has 20 I/O pins 302B, die 300C has 16 I/O pins 302C, die 300D has 9 I/O pins 302D, and die 300E has 12 I/O pins 302E. In other examples, the die may be a depopulated die where the die has a shape to accommodate a larger number of I/O pins than the die actually includes. For example, as illustrated in FIG. 3F, the die 300F has a shape that is configured to accommodate 25 I/O, but since the die 300F is depopulated due to the application, the number of I/O pins is only 21 I/O pins 302F.

Since the leadframe 200 illustrated in FIG. 2 has 25 contact pads 202, the number of I/O pins 302A-302F in the dies 300A-300F is limited to 25. The leadframe 200, however, can be used with each of the different configurations of the dies 300A-300F, where the dies each have a different number of I/O pins. Thus, one interchangeable leadframe, such as the leadframe 200 illustrated in FIG. 2, can be used with each and every die 300A-300F in different IC packages. Therefore, the leadframe 200 is an interchangeable leadframe 200 that can be used in multiple applications thereby reducing the number of different leadframes required for different IC packages, which decreases inventory and fabrication, and improves design flexibility.

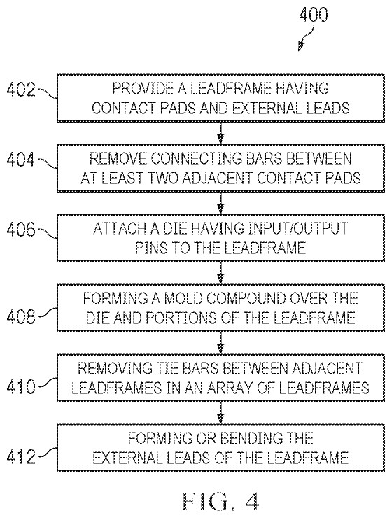

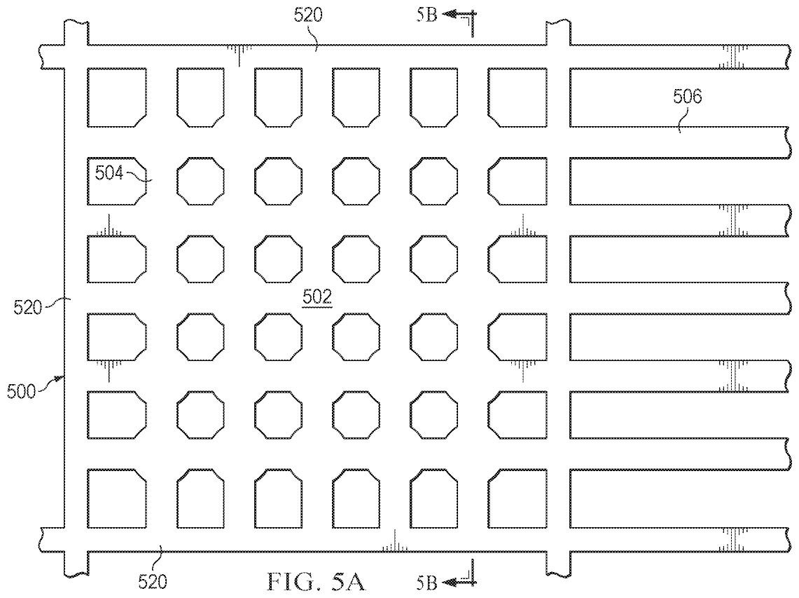

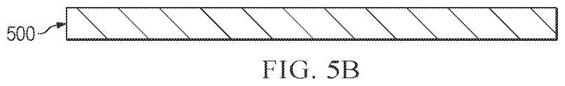

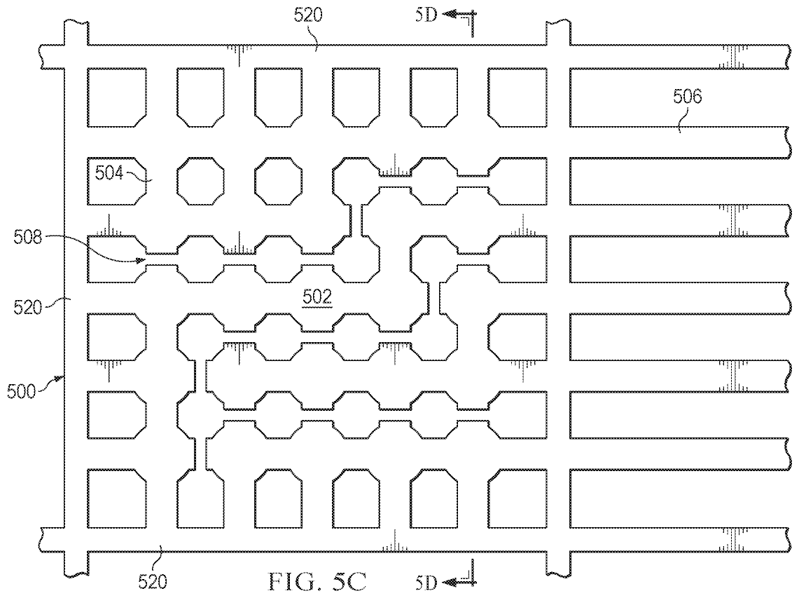

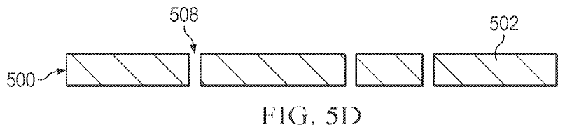

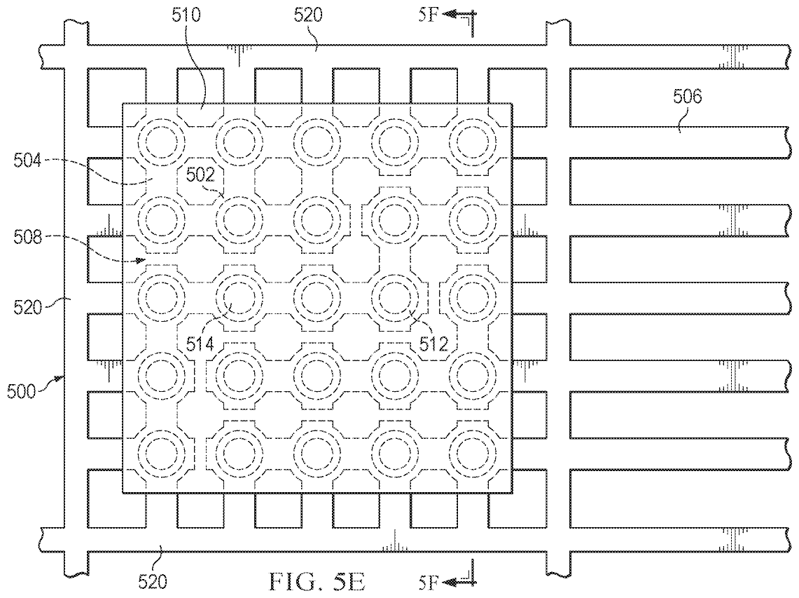

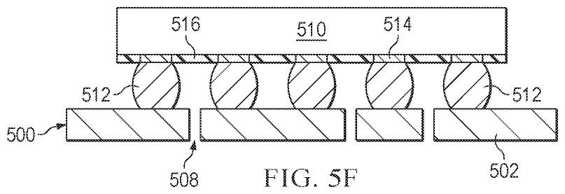

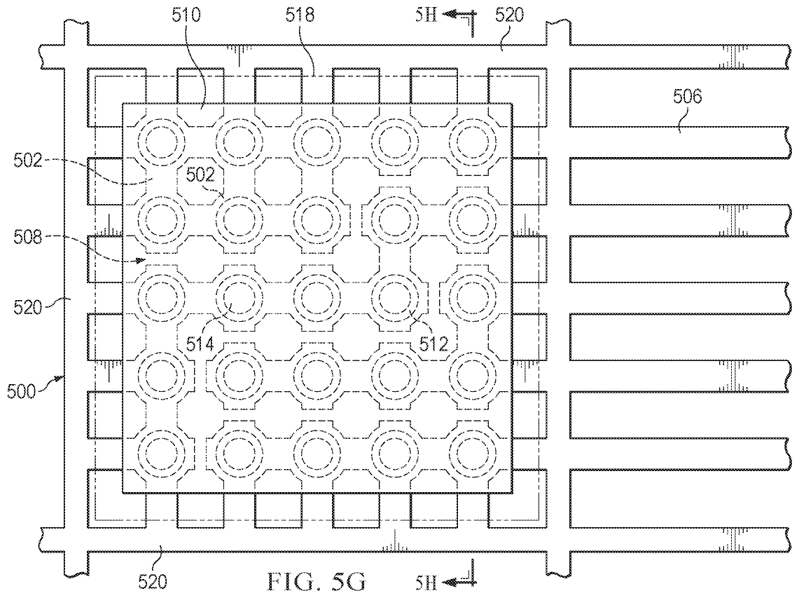

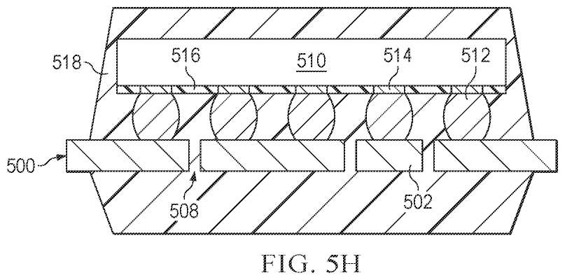

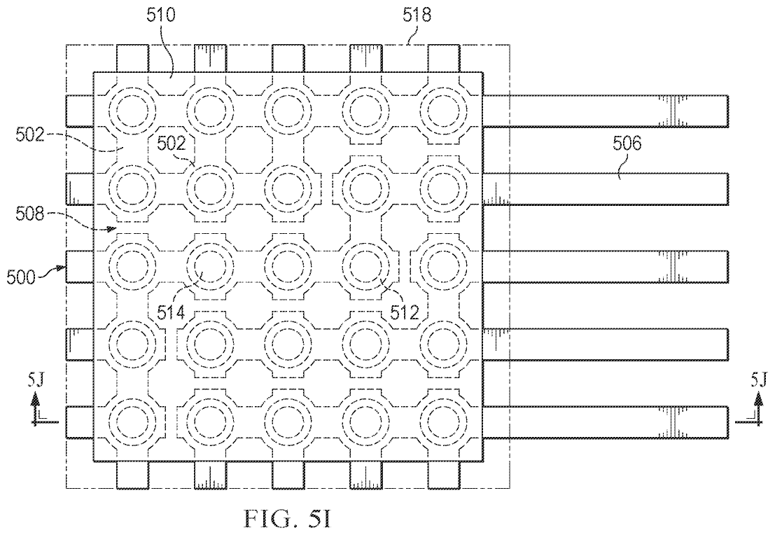

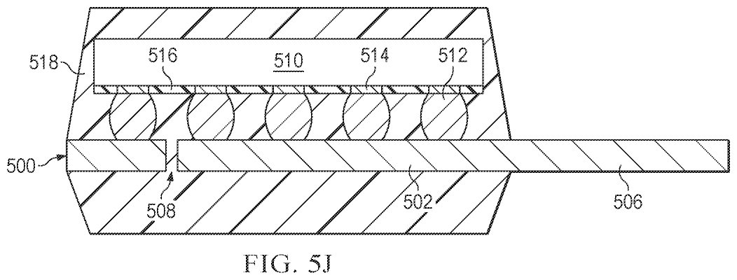

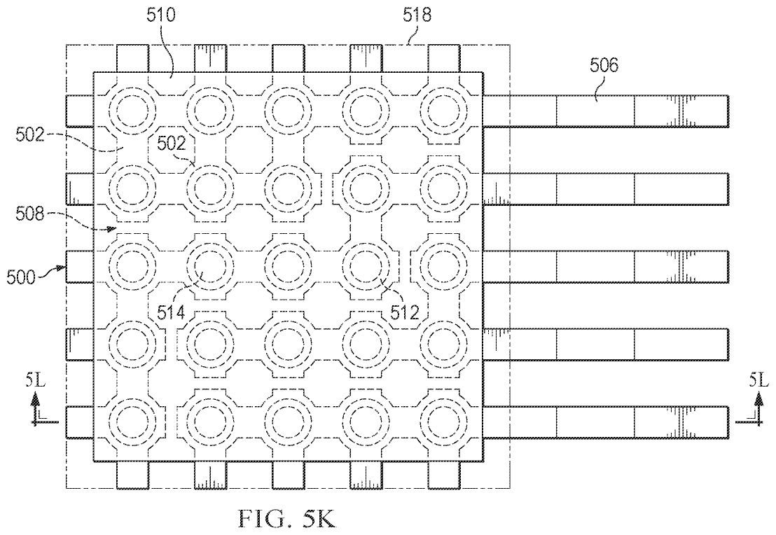

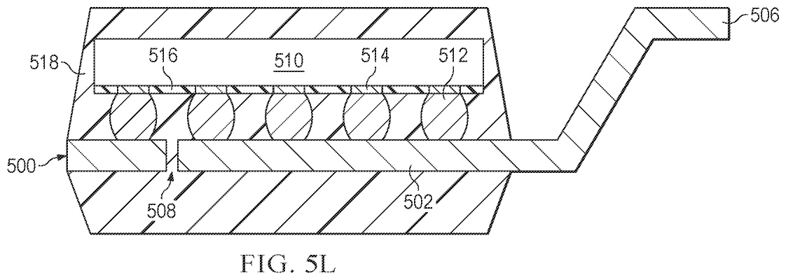

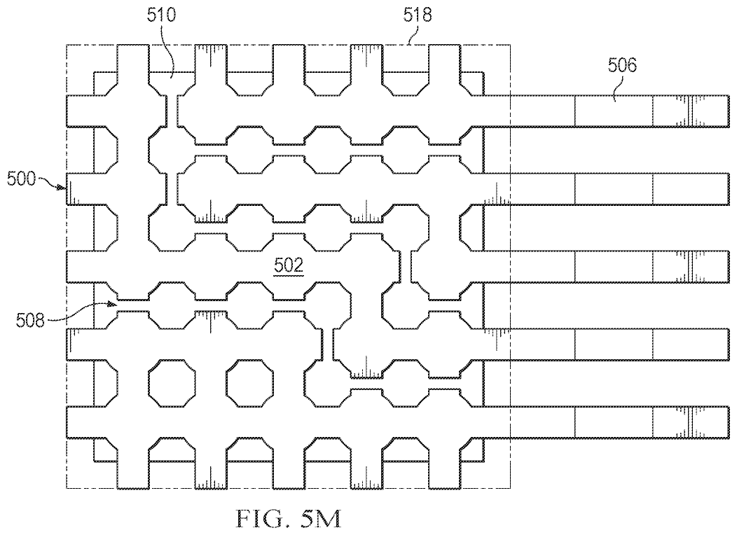

FIG. 4 is a block diagram flow chart explaining a fabrication process 400 and FIGS. 5A-5M illustrate the fabrication process associated with the formation of the electronic device 100A illustrated in FIG. 1A. Though depicted sequentially as a matter of convenience, at least some of the actions shown can be performed in a different order and/or performed in parallel. Alternatively, some implementations may perform only some of the actions shown. Still further, although the example illustrated in FIGS. 4 and 5A-5M is an example method illustrating the example configuration of FIG. 1A, other methods and configurations are possible. It is understood that although the method illustrated in FIGS. 4 and 5A-5M the fabrication process of a single electronic device, the process applies to an array of electronic devices. Thus, after fabrication of the array of electronic device the array is singulated to separate each electronic device from the array. In addition, in the description to follow FIGS. 5A, 5C, 5E, 5G, 5I, and 5K are top views of the fabricating process and FIGS. 5B, 5D, 5F, 5H, 5J, and 5L are the corresponding cross-sectional views of the fabricating process taken along the cross-section lines indicated in the top view figures.

Referring to FIGS. 4 and 5A-5M, at 402, the fabrication process of an electronic device begins with a leadframe 500 that includes contact pads 502 where adjacent contact pads 502 are connected to each other via connecting bars 504, see FIGS. 5A and 5B. The leadframe 500 further includes external leads 506 connected to a row or column of contact pads 502. For simplicity, a single in-line (SIP) leadframe will be described herein and illustrated in the figures. It is to be understood, however, that other types of leadframes (e.g., DIP) can be utilized in the described process. At 404, at least one connecting bar 504 between adjacent contact pads 502 is trimmed (removed) via a laser process resulting in a slot 508 defined between adjacent contact pads 502 resulting in the configuration of FIGS. 5C and 5D. The removal of connecting bars 504 between adjacent contact pads 502 is a process referenced as mechanically programming the leadframe 500 to the desired configuration. As illustrated in FIGS. 5C and 5D, numerous connecting bars 504 have been removed via the laser process. Thus, depending on the application of the electronic device, any number of connecting bars 504 may be removed between adjacent contact pads 502 to configure the leadframe 500 to accept any configuration of die.

In an alternative example, the leadframe can be mechanically programmed to add connecting bars between adjacent contact pads. Specifically, the leadframe can be provided on a substrate or in a molded material where all the contact pads are disconnected from each other. In addition, the contact pads may or may not be disconnected from the external leads. In this alternative example, during the mechanical programming of the leadframe, the connecting bars can be formed between adjacent contact pads to mechanically program the leadframe to the desired configuration. To accomplish this, slots or channels can be etched into substrate or molded material to expose adjacent contact pads. An electrically conductive material (e.g., copper) can then be deposited in the slot or channel to electrically connect the adjacent contact pads.

At 406, a die (e.g., flip-chip die) 510 is attached to the leadframe 500 via interconnects (e.g., solder balls) 512 resulting in the configuration of FIGS. 5E and 5F. The die 510 includes I/O pins 514 that align with the contact pads 502 on the leadframe 500 and are connected to each other via the interconnects 512. The die 510 may include an optional passivation layer 516. At 408, a mold compound 518 is formed over the electronic device such that the mold compound 518 covers the leadframe 500 except for the leads 506 resulting in the configuration of FIGS. 5G and 5H. In addition, the mold compound 518 encapsulates the die 510 and the interconnects 512. At 410, tie bars 520, as shown in FIGS. 5G and 5H are removed via a trimming process (e.g., laser, sawing, punch press, etc.) resulting in the configuration of FIGS. 5I and 5J. The tie bars 520 are used to connect adjacent leadframes 500 together to form an array of leadframes for fabrication. At 412, the external leads 506 of the leadframe 500 are then formed or bent (if applicable) resulting in the configuration of FIGS. 5K-5M, where FIG. 5K is a top view, FIG. 5L is a cross-sectional view taken along lines K-K of FIG. 5K, and FIG. 5M is a bottom view of FIG. 5K.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a leadframe having a plurality of contact pads, at least two adjacent contact pads of the plurality of contact pads being disconnected from each other via a slot;
a die having a plurality of input/output pins, the plurality of input/output pins connected to respective contact pads of the plurality of contact pads on the leadframe;
a plurality of interconnects connecting the plurality of input/output pins to the respective contact pads; and
a mold compound encapsulating the die and the plurality of interconnects.

2. The electronic device of claim 1, wherein the leadframe further includes a plurality of leads that are connected to the plurality of contact pads, the plurality of leads extending away from at least one side of the mold compound.

3. The electronic device of claim 2, wherein the leads of the leadframe are electroplated with a solder plating.

4. The electronic device of claim 1, wherein a number of the plurality of input/output pins of the die is the same as a number of the plurality of contact pads of the leadframe.

5. The electronic device of claim 1, wherein a number of the plurality of input/output pins of the die is less than a number of the plurality of contact pads of the leadframe.

6. The electronic device of claim 1, the plurality of input/output pins of the die are connected to the plurality of contact pads of the leadframe via electrically conductive pillars and interconnects.

7. The electronic device of claim 1, wherein the die includes a passivation layer disposed on an active surface of the die.

8. The electronic device of claim 1, wherein the leadframe is electroplated with a nickel palladium plating.

9. The electronic device of claim 1, wherein the electronic device is one of a single in-line integrated circuit package and a dual in-line integrated circuit package.

10. The electronic device of claim 1, wherein the die is a flip-chip die.

11. A method of fabricating an electronic device comprising:
providing a leadframe, the leadframe having a plurality of contact pads and a plurality of leads connected to the plurality contact pads;
forming a slot between at least two adjacent contact pads of the plurality of contact pads to disconnect the at least two adjacent contact pads from each other;
attaching a die to the leadframe; and
forming a mold compound over a portion of the leadframe having the plurality of contact pads and over the die.

12. The method of claim 11, wherein attaching the die to the leadframe includes providing the die having a plurality of input/output pins and attaching the plurality of input/output pins to respective contact pads of the plurality of contact pads.

13. The method of claim 12, wherein the die is a flip-chip die, the flip-chip die including metal pillars aligned with the plurality of input/output pins, the method further comprising attaching the metal pillars to the respective contact pads of the plurality of contact pads via an interconnect.

14. The method of claim 11, wherein forming the slot between the at least two adjacent contact pads includes trimming a tie bar connecting the at least two adjacent contact pads via a laser.

15. The method of claim 11, wherein a number of the plurality of input/output pins of the die is the same as a number of the plurality of contact pads of the leadframe.

16. The method of claim 11, wherein a number of the plurality of input/output pins of the die is less than a number of the plurality of contact pads of the leadframe.

17. The method of claim 11, wherein the plurality of leads extend from one side of the mold compound to form a single in-line integrated circuit.

18. The method of claim 11, wherein the plurality of leads extend from opposite sides of the mold compound to form a dual in-line integrated circuit.

19. The method of claim 11, wherein prior to attaching a die to the leadframe, the method further comprising depositing a nickel palladium plating layer on the leadframe via an electroplating process.

20. The method of claim 11 further comprising depositing a solder plating on the leads via an electroplating process.
